(19) United States
(12) Patent Application Publication
(10) Pub. No.: US 2025/0142908 A1
(43) Pub. Date: May 1, 2025

(54) SEMICONDUCTOR DEVICE INCLUDING A VERTICAL CHANNEL TRANSISTOR

(71) Applicant: SAMSUNG ELECTRONICS CO., LTD., SUWON-SI (KR)

(72) Inventors: Hyungki CHO, Suwon-si (KR); Seongjae BYEON, Suwon-si (KR)

(21) Appl. No.: 18/738,107

(22) Filed: Jun. 10, 2024

(30) Foreign Application Priority Data
Oct. 27, 2023 (KR) 10-2023-0145936

(51) Int. Cl. H01L 29/10; H01L 23/31; H01L 23/522; H01L 27/06; H01L 29/24

(52) U.S. Cl. CPC H10D 62/314; H01L 23/3185; H01L 23/5223; H10D 62/80; H10D 84/811

(57) ABSTRACT

A semiconductor device includes: a mold insulating pattern positioned on a substrate; an upper conductive line extending in a first horizontal direction on the substrate; a channel structure including a vertical channel portion that faces a side surface of the upper conductive line, and is in contact with a first side wall of the mold insulating pattern, wherein the vertical channel portion extends in a vertical direction; a first gate dielectric layer at least partially surround a surface of the channel structure; and a second gate dielectric layer positioned between the upper conductive line and the first gate dielectric layer on the channel structure, wherein the mold insulating pattern includes a body and protrusion, wherein the body extends in the first horizontal direction, and the protrusion protrude in a second horizontal direction that intersects with the first horizontal direction.

### CROSS-REFERENCE TO RELATED APPLICATION

This application claims priority under 35 U.S.C. § 119 to Korean Patent Application No. 10-2023-0145936, filed on Oct. 27, 2023, in the Korean Intellectual Property Office, the disclosure of which is incorporated by reference herein in its entirety.

### TECHNICAL FIELD

Embodiments of present inventive concept relate to a semiconductor device. More particularly, embodiments of the present inventive concept relate to a semiconductor device including a vertical channel transistor.

### DISCUSSION OF THE RELATED ART

Down-scaling of semiconductor devices is progressing rapidly, and accordingly, vertical channel transistors with channel layers including oxide semiconductor materials have been under development to reduce leakage current through channel regions.

### SUMMARY

According to embodiments of the present inventive concept, a semiconductor device includes: a mold insulating pattern positioned on a substrate; an upper conductive line extending in a first horizontal direction on the substrate; a channel structure including a vertical channel portion that faces a side surface of the upper conductive line, and is in contact with a first side wall of the mold insulating pattern, wherein the vertical channel portion extends in a vertical direction; a first gate dielectric layer at least partially surround a surface of the channel structure; and a second gate dielectric layer positioned between the upper conductive line and the first gate dielectric layer on the channel structure, wherein the mold insulating pattern includes a body and protrusion, wherein the body extends in the first horizontal direction, and the protrusion protrude in a second horizontal direction that intersects with the first horizontal direction.

According to embodiments of the present inventive concept, a semiconductor device includes: a plurality of lower conductive lines positioned on a substrate and arranged in parallel to each other; a mold insulating pattern positioned on the plurality of lower conductive lines, and extending in a first horizontal direction, wherein the mold insulating pattern defines a transistor region; a plurality of channel structures arranged along the first horizontal direction in the transistor region, wherein each of the plurality of channel structures includes a vertical channel portion that faces a side wall of the mold insulating pattern; a first gate dielectric layer overlapping a side wall of the plurality of channel structures; a plurality of upper conductive line positioned on the plurality of channel structures in the transistor region, and including a side wall that faces the vertical channel portion of each of the plurality of channel structures, wherein the plurality of upper conductive lines extend in the first horizontal direction; a second gate dielectric layer positioned between the plurality of channel structures and the plurality of upper conductive lines; and a plurality of conductive contact patterns, each of which is connected to the vertical channel portion of each of the plurality of channel structures, wherein a width in a second horizontal direction of a first portion, of the mold insulating pattern, that faces the vertical channel portion is greater than a width in the second horizontal direction of a second portion, of the mold insulating pattern, that does not face the vertical channel portion, wherein the second horizontal direction intersects with the first horizontal direction.

According to embodiments of the present inventive concept, a semiconductor device includes: a printed circuit region positioned on a substrate and including a plurality of printed circuits; a lower conductive line positioned on the printed circuit region and connected to the plurality of printed circuits; a mold insulating pattern positioned on the lower conductive line and including a side wall that defines a transistor region; a channel structure positioned in the transistor region, and including a lower surface and a vertical portion, wherein the lower surface of the channel structure is in contact with an upper surface of the lower conductive line, and the vertical channel portion of the channel structure faces the side wall of the mold insulating pattern; a first gate dielectric layer and a second gate dielectric layer covering the channel structure in the transistor region; an upper conductive line positioned on the first gate dielectric layer and the second gate dielectric layer in the transistor region, and including a side wall that faces the vertical channel portion of the channel structure; and a conductive contact pattern connected to the vertical channel portion of the channel structure, wherein the channel structure includes an oxide semiconductor layer, and the mold insulating pattern includes a protrusion that protrudes in a direction that intersects with a direction in which the mold insulating pattern extends, wherein the protrusion of the mold insulating pattern has a preset thickness and is in contact with the vertical channel portion.

### BRIEF DESCRIPTION OF THE DRAWINGS

The above and other aspects of the present inventive concept will become more apparent by describing in detail embodiments thereof, with reference to the accompanying drawings, in which:

FIG. 1 is a flat layout diagram showing components of a semiconductor device according to embodiments of the present inventive concept;

FIG. 2A is a cross-sectional view taken along line A-A′ of FIG. 1;

FIG. 2B is a cross-sectional view taken along line B-B′ of FIG. 1;

FIG. 3 is an enlarged cross-sectional view of a portion denoted by “EX” in FIG. 1;

FIGS. 4A, 4B, 4C, 5A, 5B, 5C, 6A, 6B, 6C, 7A, 7B, 7C, 8A, 8B, 8C, 9, 10, and 11 show sequential processes of a method of manufacturing a semiconductor device, according to embodiments of the present inventive concept, wherein FIGS. 4A, 5A, 6A, 7A, and 8A are flat layout diagrams showing some components according to the sequential processes of the method of manufacturing the semiconductor device of FIG. 1, FIGS. 4B, 5B, 6B, 7B, 8B, 9, 10, and 11 are cross-sectional views showing sequential processes with respect to a region corresponding to a cross-section taken along line A-A′ of FIG. 1, and FIGS. 4C, 5C, 6C, 7C, and 8C are cross-sectional views showing sequential processes with respect to a region corresponding to a cross-section taken along line B-B′ of FIG. 1.

### DETAILED DESCRIPTION OF THE EMBODIMENTS

Hereinafter, embodiments of the present inventive concept will be described in detail with reference to the accompanying drawings. In the drawings, like components are assigned like reference numerals throughout the specification and the drawings, and overlapping descriptions thereof will be omitted or briefly discussed.

The embodiments of the present inventive concept can be subjected to various modifications and have various forms, and embodiments of the present inventive concept are illustrated in the drawings and described in detail hereinafter. However, it should be understood that the scope of the present inventive concept is not limited to the embodiments discussed herein, but rather includes all modifications, equivalents, and substitutions within the spirit and technical scope of the present inventive concept.

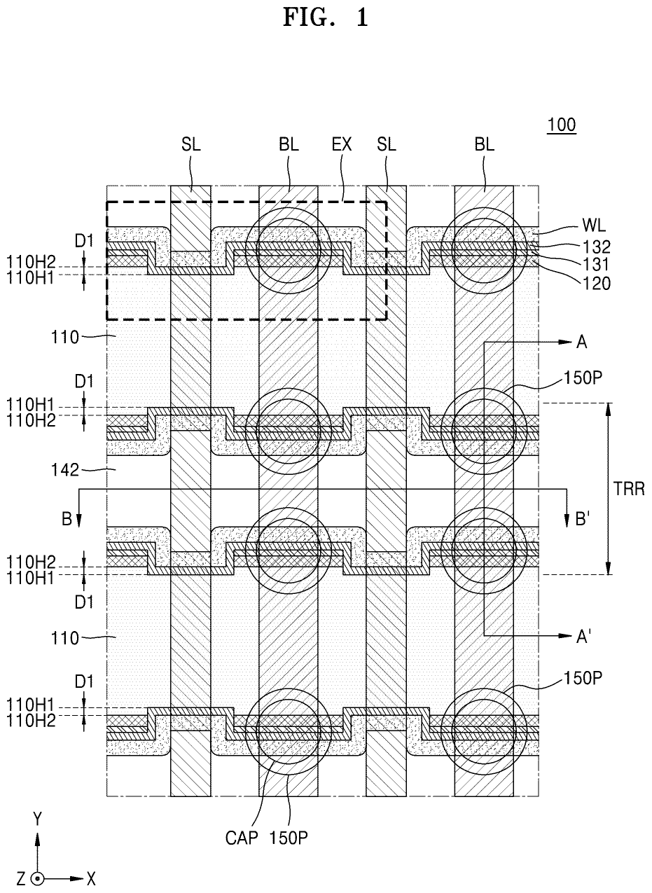

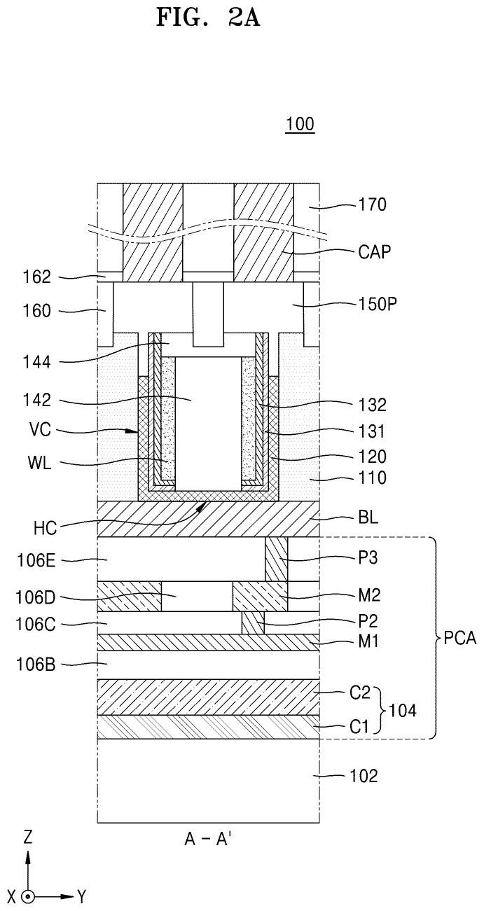

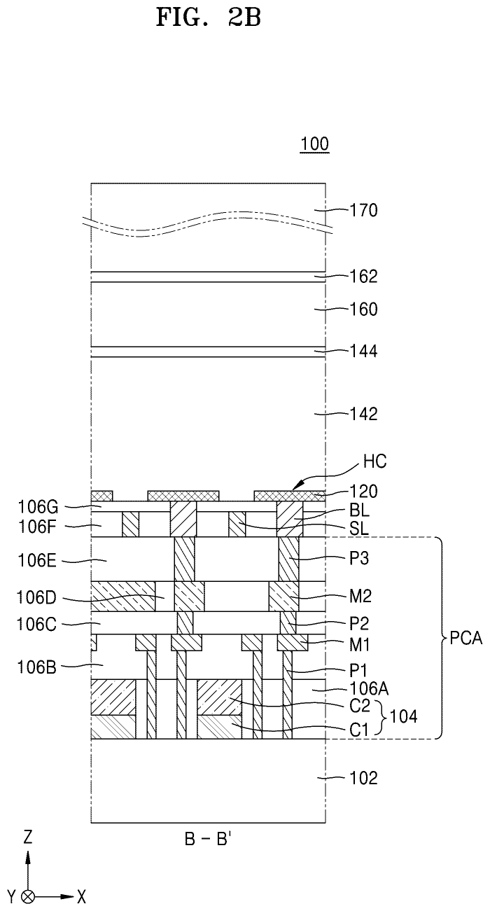

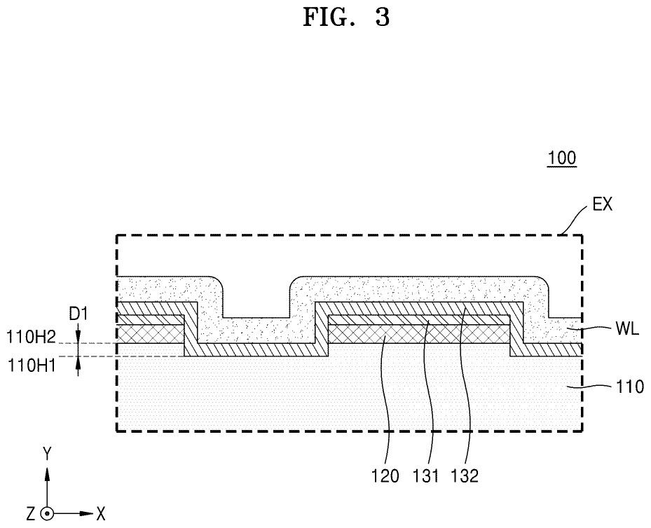

FIG. 1 is a flat layout diagram showing components of a semiconductor device 100 according to embodiments of the present inventive concept. FIG. 2A is a cross-sectional view taken along line A-A′ of FIG. 1. FIG. 2B is a cross-sectional view taken along line B-B′ of FIG. 1, and FIG. 3 is an enlarged cross-sectional view of a portion denoted by “EX” in FIG. 1.

Referring to FIGS. 1, 2A, 2B, and 3, the semiconductor device 100 may include a substrate 102, a printed circuit assembly PCA positioned on the substrate 102 and including a plurality of printed circuits, a plurality of bit lines BL arranged on the printed circuit assembly PCA, and a plurality of shielding lines SL.

According to embodiments of the present inventive concept, the substrate 102 may include silicon, for example, single crystal silicon, poly-crystalline silicon, or amorphous silicon. According to embodiments of the present inventive concept, the substrate 102 may include at least one of germanium (Ge), silicon germanium (SiGe), silicon carbide (SiC), gallium arsenide (GaAs), indium arsenide (InAs), or indium phosphide (InP). According to embodiments of the present inventive concept, the substrate 102 may include a conductive region, for example, a well doped with impurities or a structure doped with impurities.

Each of the plurality of bit lines BL may be connected to at least one printed circuit among the plurality of printed circuits included in the printed circuit assembly PCA. Each of the plurality of shielding lines SL may be floated. The plurality of bit lines BL may be respectively insulated from the plurality of shielding lines SL by an insulating interlayer 106F. The plurality of shielding lines SL may be covered with the insulating interlayer 106G, and the plurality of bit lines BL may penetrate the insulating interlayers 106F and 106G in a vertical direction (Z direction). The plurality of bit lines BL may be connected to the printed circuits that are included in the printed circuit assembly PCA through a portion selected from among a plurality of conductive plugs P1, P2, and P3 and a plurality of wiring layers M1 and M2 included in the printed circuit assembly PCA.

The printed circuit assembly PCA may include a plurality of core circuits 104. The plurality of core circuits 104 may include a first conductive pattern C1 and a second conductive pattern C2 sequentially positioned on the substrate 102. The first conductive pattern C1 and the second conductive pattern C2 may constitute various circuit elements for controlling functions of a semiconductor device that is positioned on the printed circuit assembly PCA. According to embodiments of the present inventive concept, the printed circuit assembly PCA may further include various active elements such as transistors, and various passive elements, such as capacitors, resistors, inductors, etc.

According to embodiments of the present inventive concept, the plurality of printed circuits included in the printed circuit assembly PCA may include a sub-word line driver block SWD, a sense amplifier block S/A, and/or a control logic, although the present inventive concept is not limited thereto. The plurality of printed circuits included in the printed circuit assembly PCA may include an n-channel metal oxide semiconductor (NMOS) transistor and a p-channel metal oxide semiconductor (PMOS) transistor. The plurality of printed circuits may be electrically connected to conductive lines, for example, the plurality of bit lines BL that are positioned on the printed circuit assembly PCA through the plurality of conductive plugs P1, P2, and P3 and the plurality of wiring layers M1 and M2.

In the printed circuit assembly PCA, some portions among the plurality of core circuits 104, the plurality of conductive plugs P1, P2, and P3, and the plurality of wiring layers M1 and M2, may be maintained at a predetermined insulating distances by a plurality of insulating interlayers 106A, 106B, 106C, 106D, and 106E. For example, each of the plurality of insulating interlayers 106A, 106B, 106C, 106D, and 106E may be formed of an oxide layer, a nitride layer, or a combination thereof, although not limited thereto.

According to embodiments of the present inventive concept, the printed circuit assembly PCA on the substrate 102 may be omitted. In this case, the printed circuit assembly PCA may be positioned in another region that is spaced from a region illustrated in FIGS. 2A and 2B on the substrate 102. According to embodiments of the present inventive concept, the printed circuit assembly PCA may be positioned in a region that is spaced from a cell array region including a transistor region TRR in a side direction.

The plurality of bit lines BL may be respectively spaced from the plurality of shielding lines SL on the substrate 102 in a first horizontal direction (X direction), and the plurality of bit lines BL and the plurality of shielding lines SL may extend in a second horizontal direction (Y direction) that is substantially perpendicular to the first horizontal direction (X direction). The plurality of bit lines BL and the plurality of shielding lines SL may extend in parallel to each other in the second horizontal direction (Y direction). According to embodiments of the present inventive concept, the plurality of bit lines BL may be formed of at least one of titanium (Ti), titanium nitride (TiN), tantalum (Ta), tantalum nitride (TaN), molybdenum (Mo), ruthenium (Ru), tungsten (W), tungsten nitride (WN), cobalt (Co), nickel (Ni), titanium silicon (TiSi), titanium silicon nitride (TiSiN), tungsten silicon (WSi), tungsten silicon nitride (WSiN), tantalum silicon (TaSi), tantalum silicon nitride (TaSiN), ruthenium titanium nitride (RuTiN), cobalt silicon (CoSi), nickel silicon (NiSi), polysilicon, or a combination thereof, although the present inventive concept is not limited thereto. In the present specification, the bit lines BL may also be referred to as lower conductive lines. According to embodiments of the present inventive concept, each of the plurality of shielding lines SL may be formed of at least one of tungsten (W), aluminum (Al), copper (Cu), or a combination thereof, although the present inventive concept is not limited thereto. According to embodiments of the present inventive concept, each of the plurality of shielding lines SL may include a conductive layer formed of W, Al, Cu, or a combination thereof, and an air gap or void formed inside the conductive layer.

A mold insulating pattern 110 may be positioned on the plurality of bit lines BL and the plurality of shielding lines SL. The mold insulating pattern 110 may extend in the first horizontal direction (X direction). For example, the mold insulating pattern 110 may be formed of at least one of a silicon oxide layer, a silicon nitride layer, or a combination thereof.

As illustrated in FIGS. 1 and 2A, a channel structure 120 may be aligned along the first horizontal direction (X direction) in the transistor region TRR. The channel structure 120 may include a vertical channel portion VC and a horizontal channel portion HC. The vertical channel portion VC faces a side wall of the mold insulating pattern 110, and the horizontal channel portion HC is in contact with an upper surface of a bit line BL.

In each of a plurality of channel structures 120, the vertical channel portion VC may be in contact with the side wall of the mold insulating pattern 110, and extend from the horizontal channel portion HC in the vertical direction (Z direction).

The channel structure 120 may be in contact with an upper surface of a bit line BL of the plurality of bit lines BL. According to embodiments of the present inventive concept, the channel structure 120 may be formed from an oxide semiconductor layer. In the drawings, the channel structure 120 is shown to be a single layer, however, this is only an example. The present inventive concept is not limited to this, and the channel structure 120 may include a multi-layer including two or more layers.

According to embodiments of the present inventive concept, the oxide semiconductor layer included in the channel structure 120 may be formed of at least one of indium gallium zinc oxide (InGaZnO; IGZO), Sn-IGZO, indium tungsten oxide (InWO; IWO), indium zinc oxide (InZnO; IZO), zinc tin oxide (ZnSnO; ZTO), zinc oxide (ZnO), yttrium-doped zinc oxide (YZO), indium gallium silicon oxide (InGaSiO; IGSO), indium oxide (InO), tin oxide (SnO), titanium oxide (TiO), zinc oxy-nitride (ZnON), magnesium zinc oxide (MgZnO), zirconium indium zinc oxide (ZrInZnO), hafnium indium zinc oxide (HfInZnO), tin indium zinc oxide (SnInZnO), silicon indium zinc oxide (SiInZnO), gallium zinc tin oxide (GaZnSnO), zirconium zinc tin oxide (ZrZnSnO), or a combination thereof. For example, the channel structure 120 may be formed of IGZO.

As illustrated in FIGS. 1 and 2A, a first gate dielectric layer 131 and a second gate dielectric layer 132 covering the channel structure 120, and a plurality of word lines WL covering the first and second gate dielectric layers 131 and 132 may be positioned in the transistor region TRR. The plurality of word lines WL may extend in the first horizontal line (X direction) and be arranged in parallel to each other. FIGS. 1 and 2A show a configuration in which two word lines WL are arranged in a transistor region TRR. In the present specification, the word lines WL may also be referred to as upper conductive lines. In the transistor region TRR, a word line WL may be in contact with the second gate dielectric layer 132, and the word line WL may face the plurality of channel structures 120 in the second horizontal direction (Y direction) with the first and second gate dielectric layers 131 and 132 disposed therebetween.

As illustrated in FIG. 1, each of the plurality of word lines WL may include a first portion and a second portion. The first portion of each of the plurality of word lines WL faces the channel structure 120 with the first and second gate dielectric layers 131 and 132 disposed between the first portion of the plurality of word lines WL and the channel structure 120. The second portion of each of the plurality of word lines WL faces the mold insulating pattern 110 with the second gate dielectric layers 132 disposed the second portion of the plurality of word lines WL and the mold insulating pattern 110 without the channel structure 120 and the first dielectric layers 131. In each of the plurality of word lines WL, the second portion may be closer to the mold insulating pattern 110 than the first portion, in the second horizontal direction (Y direction).

As illustrated in FIG. 2A, each bit line BL may be spaced from each word line WL in the vertical direction (Z direction), with the channel structure 120 and the first and second gate dielectric layers 131 and 132 disposed therebetween. For example, the bit line BL may have an upper surface that is in contact with the channel structure 120.

In the transistor region TRR, the channel structure 120 may face one side surface of each of two word lines WL positioned in the transistor region TRR. The first and second gate dielectric layers 131 and 132 may include portions that are in contact with the plurality of channel structures 120. The second dielectric layer 132 may include portions that are in contact with the side wall of the mold insulating pattern 110. The first and second gate dielectric layers 131 and 132 may include portions, which are positioned between the one side surface of each of the two word lines WL and the vertical channel portion VC of the channel structure 120, and portions, which are positioned between a lower surface of each of the two word lines WL and the horizontal channel portion HC of the channel structure 120.

The first and second gate dielectric layers 131 and 132 may be positioned between the channel structure 120 and the word lines WL. A top surface of the channel structure 120 may be closer to the substrate 102 than top surfaces of the first gate dielectric layer 131, the second gate dielectric layer 132, the plurality of word lines WL, and the mold insulating pattern 110.

According to embodiments of the present inventive concept, each of the first and second gate dielectric layers 131 and 132 may be formed of a high dielectric layer having a greater dielectric constant than a dielectric constant of a silicon oxide layer. According to embodiments of the present inventive concept, the first gate dielectric layer 131 may have a same composition as that of the second gate dielectric layer 132. According to embodiments of the present inventive concept, the first gate dielectric layer 131 may have a different composition from that of the second gate dielectric layer 132. According to embodiments of the present inventive concept, the first and second gate dielectric layers 131 and 132 may be formed of at least one of hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), Barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), or lead scandium tantalum oxide (PbScTaO). For example, each of the plurality of word lines WL may be formed of Ti, TiN, Ta, TaN, Mo, Ru, W, WN, TiSiN, WSiN, polysilicon, or a combination thereof.

A lower insulating partition wall 142 may be positioned on the channel structure 120 between two word lines WL that are positioned in a transistor region TRR. Upper surfaces of the two word lines WL and an upper surface of the lower insulating partition wall 142 may be covered with an upper insulating partition wall 144. A width of the upper insulating partition wall 144 may be greater than that of the lower insulating partition wall 142 in the second horizontal direction (Y direction). For example, the width of the upper insulating partition wall 144 may be greater than that of each of the two word lines WL in the second horizontal direction (Y direction). For example, each of the lower insulating partition wall 142 and the upper insulating partition wall 144 may be formed from a silicon oxide layer, a silicon nitride layer, or a combination thereof.

A plurality of conductive contact patterns 150P may be positioned on the plurality of channel structures 120. Each of the plurality of conductive contact patterns 150P may be connected to a channel structure 120 of the plurality of channel structures 120. For example, each of the conductive patterns 150P may be disposed on the upper insulating partition wall 144 and the molding insulating pattern 110.

As illustrated in FIG. 1, the plurality of conductive contact patterns 150P may be positioned in a regular arrangement at constant intervals in the first horizontal direction (X direction) and the second horizontal direction (Y direction). FIG. 1 shows an example in which the plurality of conductive contact patterns 150P are arranged in a matrix structure on a plane (for example, an X-Y plane) on the substrate 102. However, the present inventive concept is not limited to thereto. For example, the plurality of conductive contact patterns 150P may be arranged in a honeycomb structure on the plane (for example, the X-Y plane) on the substrate 102. The plurality of conductive contact patterns 150P may be insulated from each other by a separation insulating layer 160.

The channel structure 120 may be spaced from a portion of the conductive contact patterns 150P. Each of the plurality of conductive contact patterns 150P may have a surface that is in contact with the channel structure 120.

The plurality of conductive contact patterns 150P may be spaced from the word lines WL with the first and second gate dielectric layers 131 and 132 disposed therebetween.

Each of the plurality of conductive contact patterns 150P may be formed from a metal layer. According to embodiments of the present inventive concept, the plurality of conductive contact patterns 150P may be formed of Ti, TiN, Ta, TaN, Mo, Ru, W, WN, TiSiN, WSiN, or a combination thereof. For example, the plurality of conductive contact patterns 150P may be a laminated structure of a conductive barrier layer formed of TiN and a conductive layer formed of W.

The semiconductor device 100 may include a plurality of capacitor structures CAP positioned on the plurality of conductive contact patterns 150P. An etch stop layer 162 and an insulating interlayer 170 may be sequentially disposed on the plurality of conductive contact patterns 150P and the separation insulating layer 160. The plurality of capacitor structures CAP may penetrate the insulating interlayer 170 and the etch stop layer 162 in the vertical direction (Z direction) and may be connected to a conductive contact pattern 150P of the plurality of conductive contact patterns 150P. For example, the etch stop layer 162 may be a silicon nitride layer, and the insulating interlayer 170 may be a silicon oxide layer.

FIG. 3 is an enlarged cross-sectional view of a portion denoted by “EX” in FIG. 1.

Referring to FIGS. 3 and 1 together, the mold insulating pattern 110 may include a body extending in the first horizontal direction (X direction), and a protrusion protruding in the second horizontal direction (Y direction). According to embodiments of the present inventive concept, the protrusion may be a plurality of protrusions that have a mirror-symmetric shape with respect to the body of the mold insulating pattern 110 and are spaced from each other. According to embodiments of the present inventive concept, the protrusion may have a rectangular shape from a plan view.

Because the mold insulating pattern 110 includes the body and the protrusion, the mold insulating pattern 110 may have different widths in the second horizontal direction (Y direction). A side wall 110H2 of the protrusion may protrude from a side wall of the body by a preset distance D1. For example, a length of a side in second horizontal direction (Y direction) of the protrusion, which has a rectangular shape from the plan view, may be the preset distance D1. According to embodiments of the present inventive concept, the preset distance D1 may be substantially equal to a thickness of the second gate electric layer 132. In this case, a maximum width in second horizontal direction (Y direction) of the mold insulating pattern 110 may be at least twice the preset distance D1, that is, at least twice the thickness of the second gate dielectric layer 132. According to embodiments of the present inventive concept, the preset distance D1 may be greater than a minimum width in second horizontal direction (Y direction) of the mold insulating pattern 110. According to embodiments of the present inventive concept, the preset distance D1 may be greater than the thickness of the second gate dielectric layer 132. In this case, a maximum width in second horizontal direction (Y direction) of the mold insulating pattern 110 may be more than twice the preset distance D1, that is, more than twice the thickness of the second gate dielectric layer 132, which is greater than a minimum width in second horizontal direction (Y direction) of the mold insulating pattern 110. The width of the molding insulating pattern 110 may be a pattern obtained by partially etching a side wall of the mold insulating pattern 110 after forming the mold insulating pattern 110. The present inventive concept may obtain a final structure in which the word line WL surrounds three sides of the channel structure 120, which includes the oxide semiconductor layer, by adding a process of partially etching the side wall of the mold insulating pattern 110. As a result, a gate characteristic improvement effect of a semiconductor device including a vertical channel semiconductor may be provided.

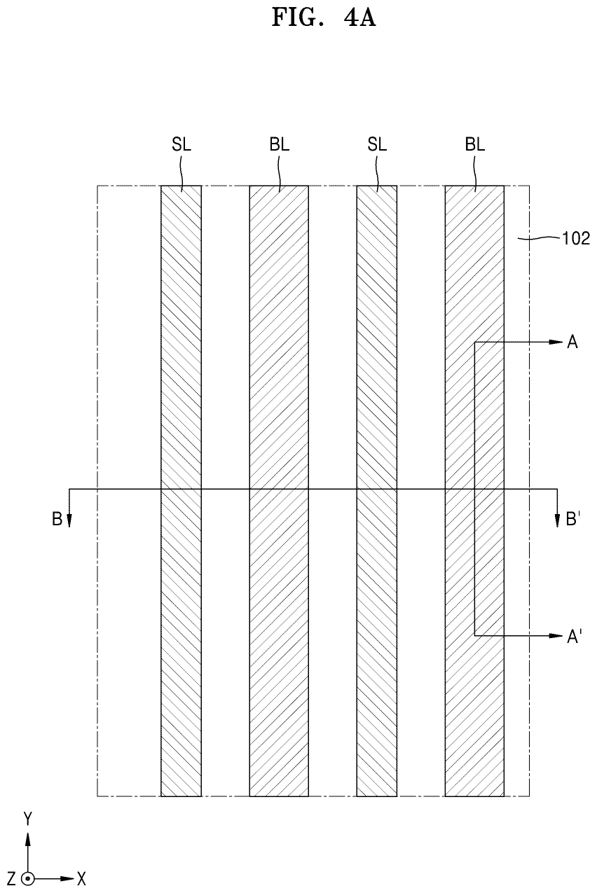

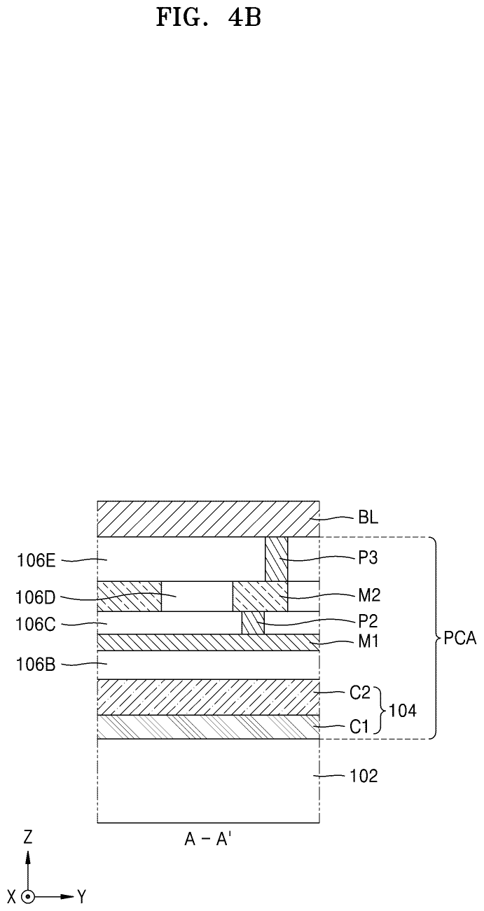

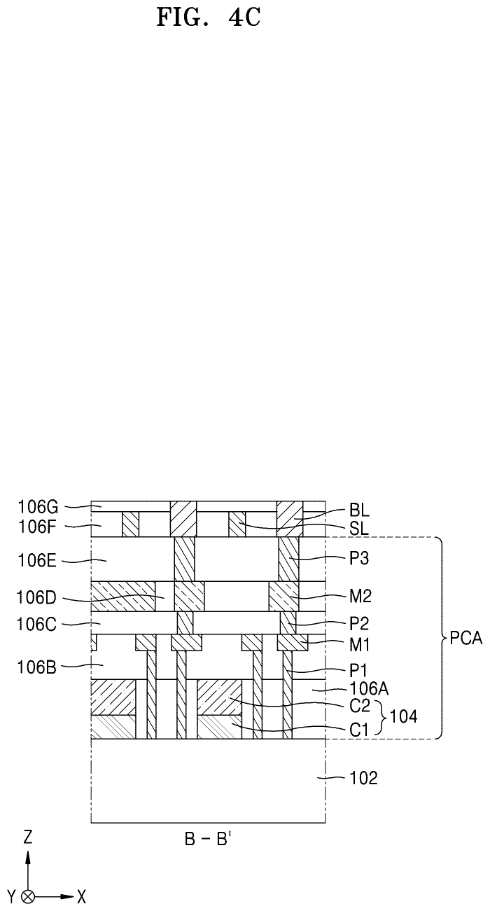

FIGS. 4A to 11 show sequential processes of a method of manufacturing a semiconductor device, according to embodiments of the present inventive concept. More specifically, FIGS. 4A, 5A, 6A, 7A, and 8A are flat layout diagrams showing components according to the sequential processes of the method of manufacturing the semiconductor device of FIG. 1. FIGS. 4B, 5B, 6B, 7B, 8B, 9, 10, and 11 are cross-sectional views showing sequential processes with respect to a region corresponding to a cross-section taken along line A-A′ of FIG. 1. FIGS. 4C, 5C, 6C, 7C, and 8C are cross-sectional views showing sequential processes with respect to a region corresponding to a cross-section taken along line B-B′ of FIG. 1. In FIGS. 4A to 11, like reference numerals, such as those shown in FIGS. 1, 2A, 2B, and 3, represent like elements, and accordingly, overlapping descriptions thereof will be omitted or briefly discussed.

Referring to FIGS. 4A, 4B, and 4C, a plurality of printed circuits including a plurality of core circuits 104, a plurality of conductive plugs P1, P2, and P3, and a plurality of wiring layers M1 and M2 may be formed on a substrate 102 to form a printed circuit assembly PCA on the substrate 102. Thereafter, a plurality of shielding lines SL, which penetrate an insulating interlayer 106F, and a plurality of bit lines BL, which penetrate the insulating interlayers 106F and 106G, may be formed on the printed circuit assembly PCA.

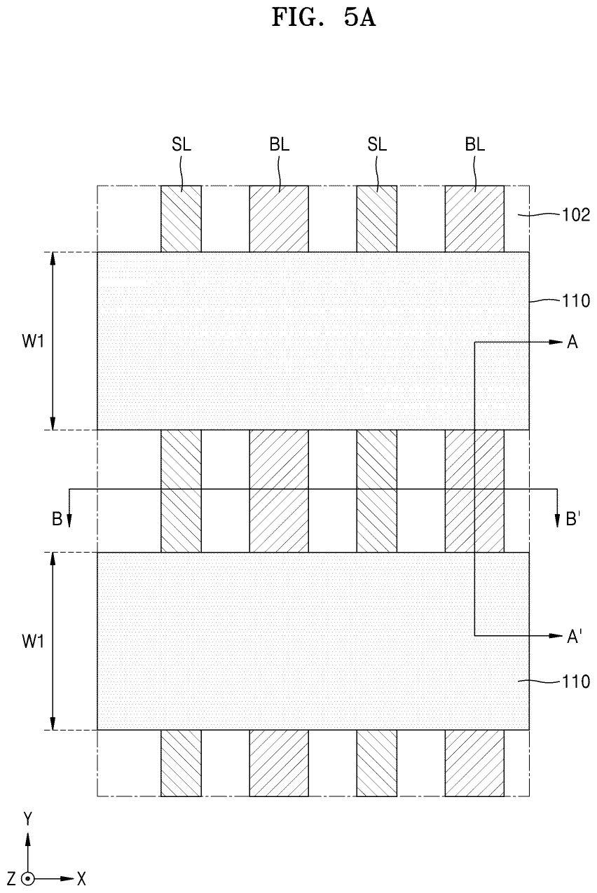

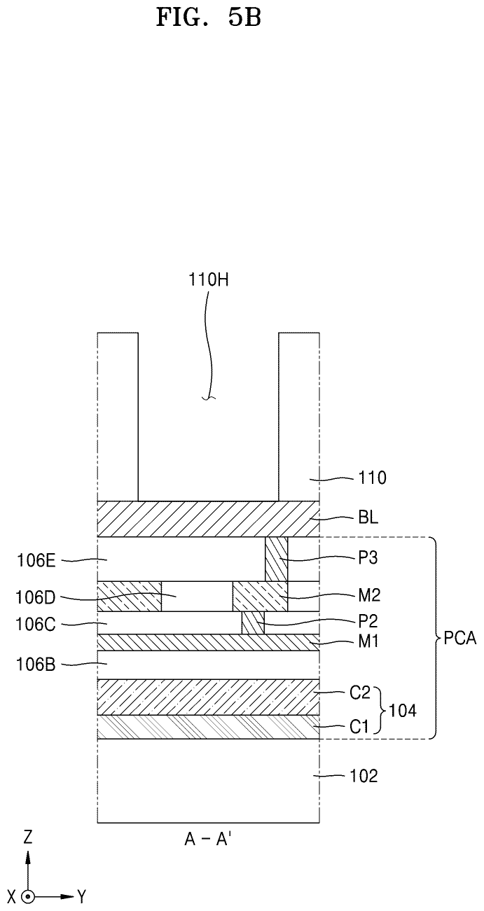

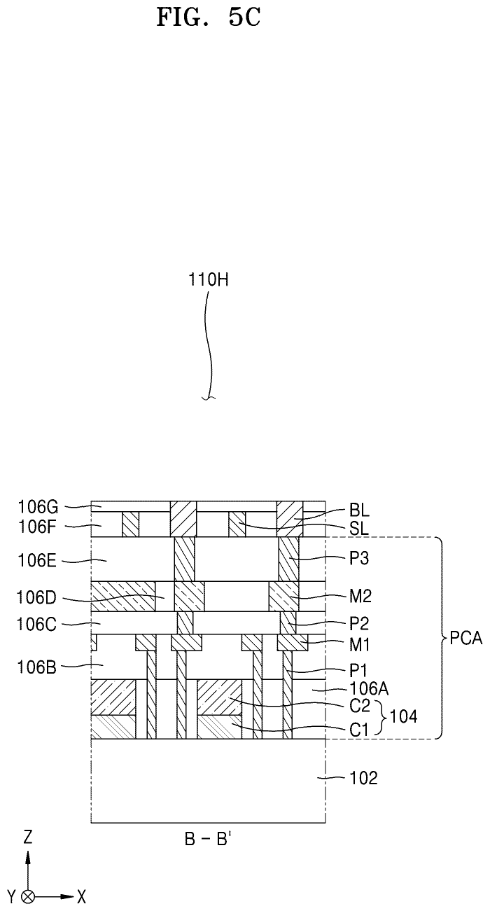

Referring to FIGS. 5A, 5B, and 5C, a mold insulating pattern 110 having a plurality of openings 110H may be formed on a resultant structure of FIGS. 4A, 4B, and 4C, on which the plurality of bit lines BL are formed. For example, the molding insulating pattern 110 may be formed on the bit lines BL. Some regions of the plurality of bit lines BL may be exposed through the plurality of openings 110H. Each of the plurality of openings 110H that are formed in the mold insulating pattern 110 may provide a transistor region TRR (see FIG. 1). According to embodiments of the present inventive concept, a width in second horizontal direction (Y direction) of each mold insulating pattern 110 extending in the first horizontal direction (X direction) may be W1.

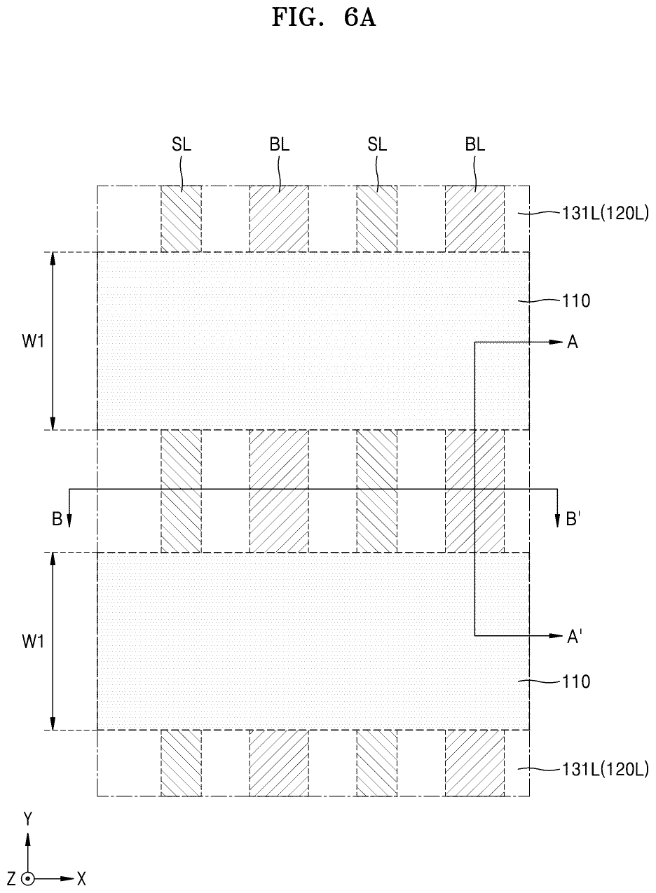

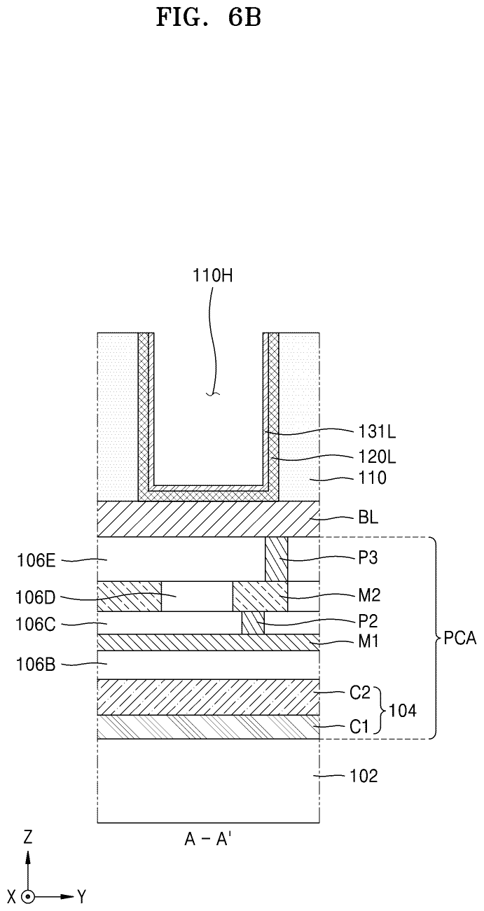

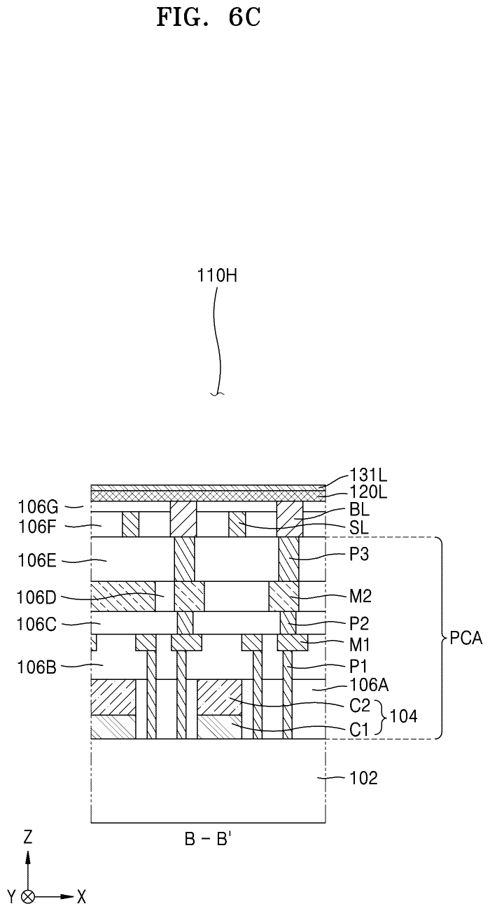

Referring to FIGS. 6A, 6B, and 6C, a channel layer 120L may be formed in the plurality of openings 110H that are formed in the mold insulating pattern 110, and a first gate dielectric layer 131L may be formed to conformally cover exposed surfaces of the channel layer 120L. For example, the channel layer 120L may be formed on regions of the plurality of bit lines BL that are exposed by the plurality of openings 110H. The channel layer 120L may be formed from, for example, an oxide semiconductor layer. The oxide semiconductor layer may be formed of, for example, IGZO (InGaZnO), Sn-IGZO, InWO (IWO), InZnO (IZO), ZnSnO (ZTO), ZnO, yttrium-doped zinc oxide (YZO), InGaSiO (IGSO), InO, SnO, TiO, ZnON, MgZnO, ZrInZnO, HfInZnO, SnInZnO, SiInZnO, GaZnSnO, ZrZnSnO, or a combination thereof. For example, the channel layer 120L may be formed of IGZO.

According to embodiments of the present inventive concept, the channel layer 120L may be formed by at least one process among a chemical vapor deposition (CVD) process, a low-pressure CVD process, a plasma enhanced CVD process, a metal organic CVD (MOCVD) process, or an atomic layer deposition (ALD) process. According to embodiments of the present inventive concept, the channel layer 120L may be formed with a thickness of about 1 nm to about 50 nm; however, the present inventive concept is not limited thereto.

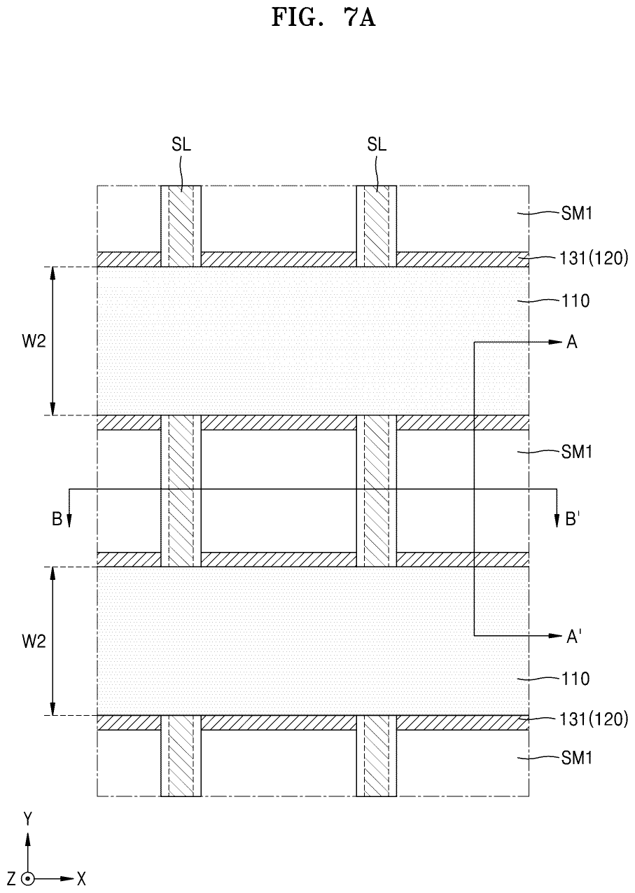

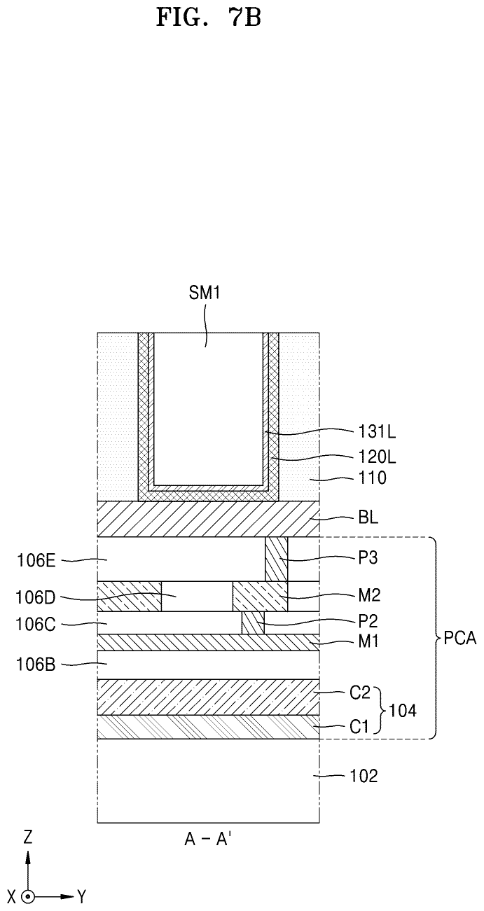

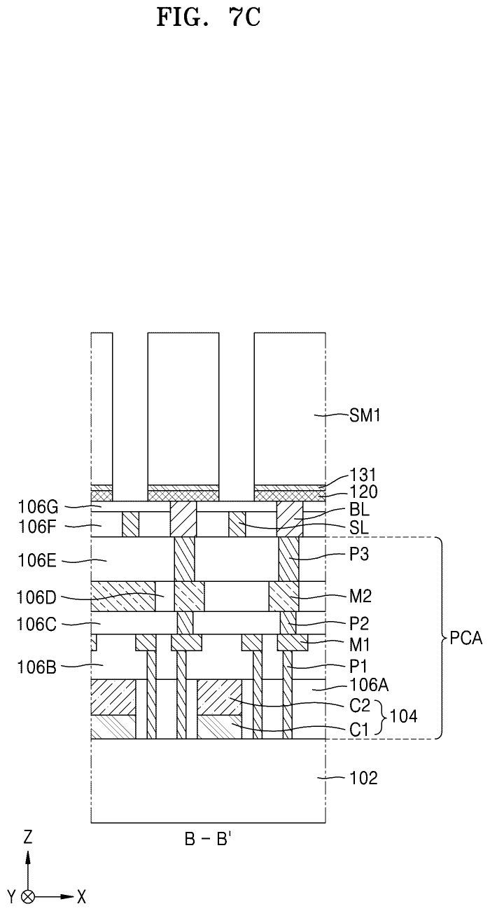

Referring to FIGS. 7A, 7B, and 7C, a sacrificial pattern SM1 covering the channel layer 120L and the first gate dielectric layer 131L may be formed on a resultant structure of FIGS. 6A, 6B, and 6C, and the channel layer 120L and the first gate dielectric layer 131L may be etched by using the sacrificial pattern SM1 as an etching mask to divide the channel layer 120L into a plurality of channel structures 120. For example, the sacrificial pattern SM1 may be formed on the first gate dielectric layer 131L in the plurality of openings 110H. The insulating interlayer 106G may be exposed between the plurality of channel structures 120 inside the plurality of openings 110H.

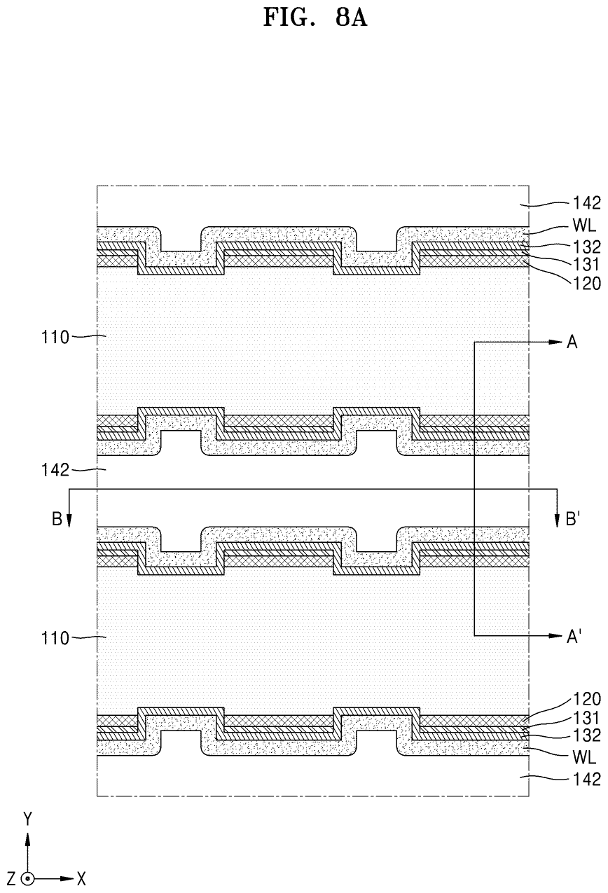

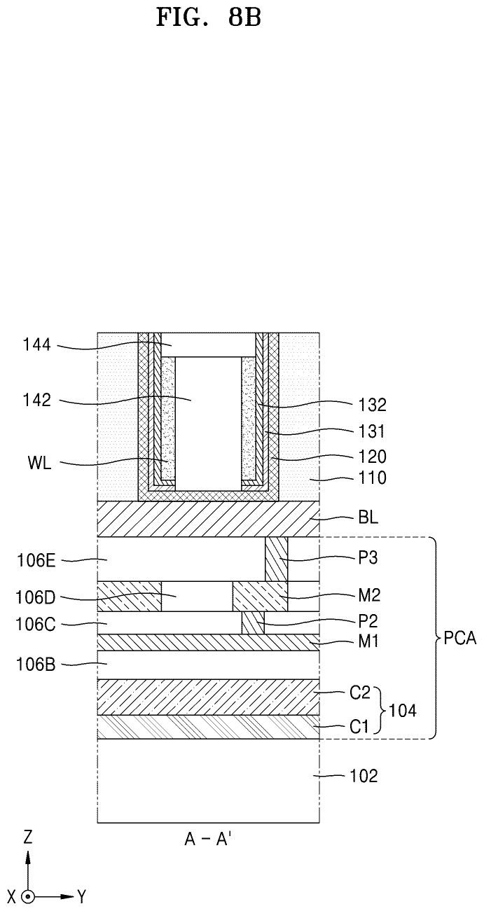

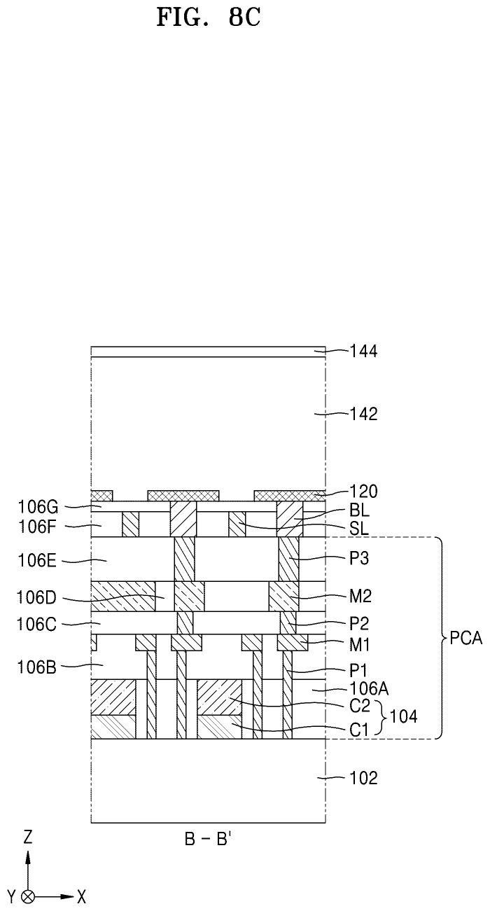

In addition, both sides of each mold insulating pattern 110 may be additionally etched to further reduce the width in second horizontal direction (Y direction) of the mold insulating pattern 110. As a result, a width W2 of the mold insulating pattern 110 in FIG. 7A may become smaller than the width W1 of the mold insulating pattern 110 in FIG. 6A. The width W2 of the mold insulating pattern 110 in FIG. 7A may be twice or more a thickness of a second gate dielectric layer 132 (see FIGS. 8A to 8C), which is to be deposited later and to have a thickness that is less than the width W1 of the mold insulating pattern 110 in FIG. 6A. For example, a thickness by which the mold insulating pattern 110 is etched may be twice or more the thickness of the second gate dielectric layer 132 (see FIGS. 8A to 8C). Referring to FIG. 3 together, the width W2 of the mold insulating pattern 110 in FIG. 7A may be twice the preset distance D1 that is less than the width W1 of the mold insulating pattern 110 in FIG. 6A.

Referring to FIGS. 8A, 8B, and 8C, upper surfaces of the plurality of channel structures 120 may be exposed by removing the sacrificial pattern SM1 from a resultant structure of FIGS. 7A, 7B, and 7C, and then, a plurality of second gate dielectric layers 132 and a plurality of word lines WL sequentially covering the plurality of channel structures 120 and the first gate dielectric layer 131, which is positioned on the upper surfaces of the plurality of channel structures 120, may be formed in the plurality of openings 110H of the mold insulating pattern 110.

According to embodiments of the present inventive concept, to form the plurality of second gate dielectric layers 132 and the plurality of word lines WL, after the upper surfaces of the plurality of channel structures 120 and the first gate dielectric layer 131 are exposed, the second gate dielectric layer 132 may be first formed to conformally cover the exposed surfaces of the plurality of channel structures 120, the first gate dielectric layer 131, and the insulating interlayer 106G. Then, the plurality of word lines WL may be formed on the second gate dielectric layer 132. During a patterning process for forming the plurality of word lines WL, a portion of the second gate dielectric layer 132 that is positioned between two word lines WL in an opening 110H may be removed. The upper surface of the channel structure 120 may be exposed between the two word lines WL in the opening 110H.

Thereafter, a lower insulating partition wall 142 that fills a space between the two word lines WL in the opening 110H may be formed in the opening 110H. Then, an upper insulating partition wall 144 that covers upper surfaces of the two word lines WL and the lower insulating partition wall 142 may be formed in the opening 110H. Upper surfaces of the upper insulating partition wall 144, the first and second gate dielectric layers 131 and 132, the word lines WL, and the mold insulating pattern 110 may form a substantially flat surface.

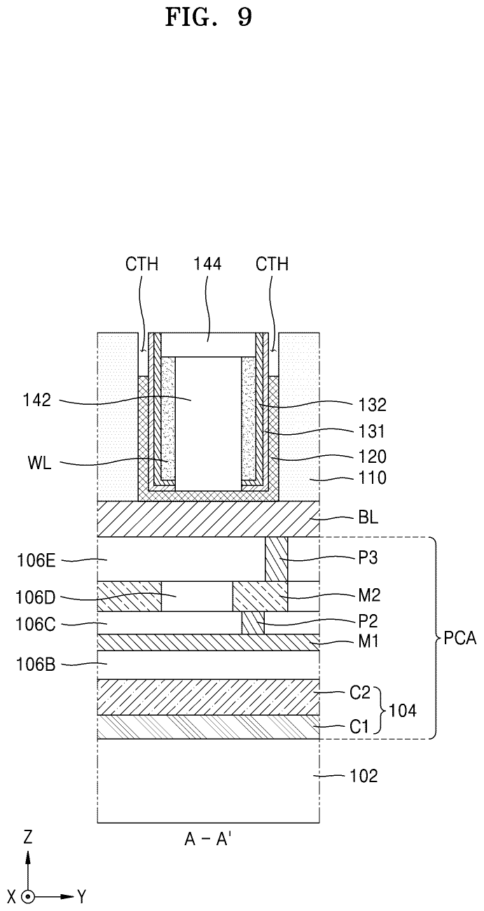

Referring to FIG. 9, a part of the exposed upper portion of each of the plurality of channel structures 120 in a resultant structure of FIGS. 8A, 8B, and 8C may be removed to lower heights of the plurality of channel structures 120. As a result, a plurality of contact spaces CTH defined by a side wall of the first gate dielectric layer 131 and a side wall of the mold insulating pattern 110 may be formed above the plurality of channel structures 120. For example, a process of removing the part of the upper portion of each of the plurality of channel structures 120 may be performed by a wet process, a dry process, or a combination thereof.

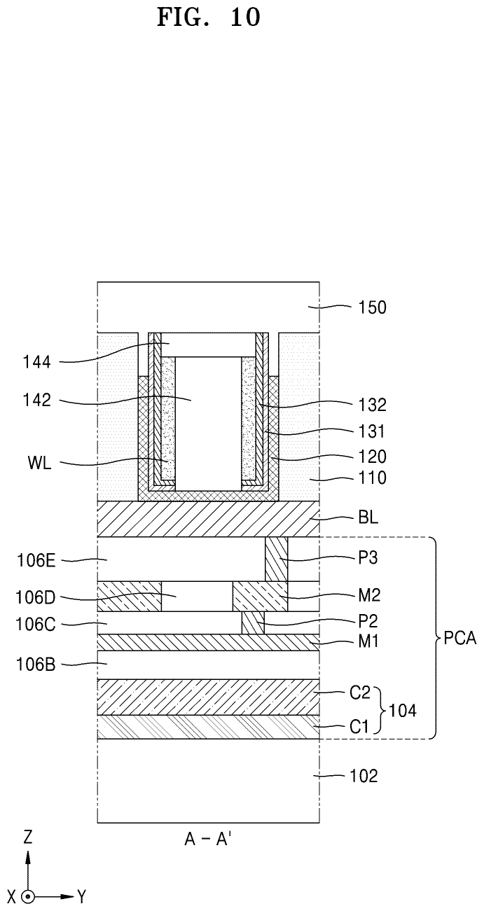

Referring to FIG. 10, a conductive layer 150 that fills the plurality of contact spaces CTH and that covers upper surfaces of the mold insulating pattern 110, the first and second gate dielectric layers 131 and 132, and the upper insulating partition wall 144 in a resultant structure of FIG. 9 may be formed. The conductive layer 150 may be formed of, for example, Ti, TiN, Ta, TaN, Mo, Ru, W, WN, TiSiN, WSiN, polysilicon, or a combination thereof. For example, the conductive layer 150 may be a laminated structure of a conductive barrier layer formed of TiN, and a conductive layer formed of W.

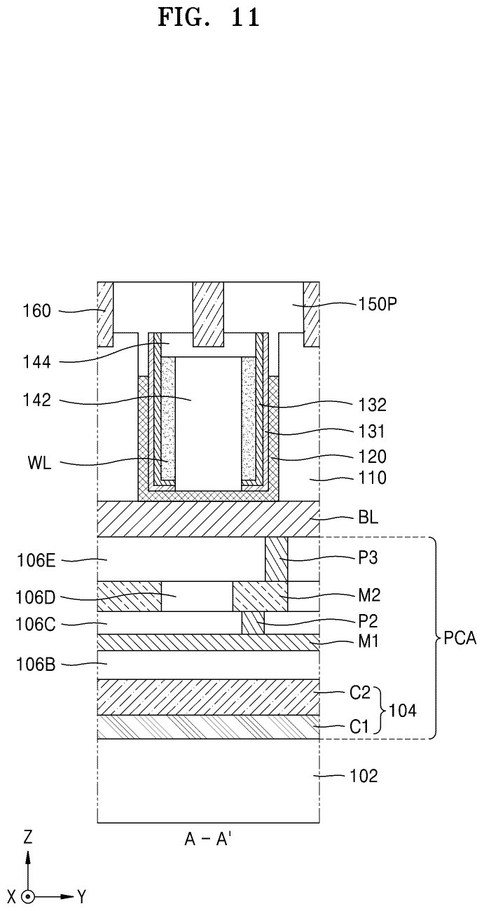

Referring to FIG. 11, some regions of the conductive layer 150 in a resultant structure of FIG. 10 may be etched to form a separation space that exposes the upper insulating partition wall 144, and a plurality of conductive contact patterns 150P may be formed from etching of the conductive layer 150. Thereafter, a separation insulating layer 160 that fills the separation space may be formed.

Thereafter, as illustrated in FIGS. 2A and 2B, an etch stop layer 162 and an insulating interlayer 170 may be formed on a resultant structure on which the plurality of conductive contact patterns 150P are formed. For example, the etch stop layer 162 may be formed on the conductive contact patterns 150P and the separating insulating pattern 160, and the insulating interlayer 170 may be formed on the etch stop layer 162. A plurality of capacitor structures CAP that penetrate the etch stop layer 162 and the insulating interlayer 170 to be connected to the plurality of conductive contact patterns 150P may be formed.

Accordingly, the method for manufacturing the semiconductor device 100 that is illustrated in FIGS. 1, 2A, 2B, and 3 has been described with reference to FIGS. 4A to 11. However, by applying various modifications and changes within the scope of the present inventive concept, semiconductor devices having various structures may be manufactured without departing from the spirit and scope of the present inventive concept.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor device comprising:
a mold insulating pattern positioned on a substrate;
an upper conductive line extending in a first horizontal direction on the substrate;
a channel structure including a vertical channel portion that faces a side surface of the upper conductive line, and is in contact with a first side wall of the mold insulating pattern, wherein the vertical channel portion extends in a vertical direction;
a first gate dielectric layer at least partially surround a surface of the channel structure; and
a second gate dielectric layer positioned between the upper conductive line and the first gate dielectric layer on the channel structure,
wherein the mold insulating pattern includes a body and protrusion, wherein the body extends in the first horizontal direction, and the protrusion protrude in a second horizontal direction that intersects with the first horizontal direction.

2. The semiconductor device of claim 1, wherein the channel structure includes an oxide semiconductor layer.

3. The semiconductor device of claim 1, wherein a side wall of the protrusion of the mold insulating pattern corresponds to the first side wall of the mold insulating pattern.

4. The semiconductor device of claim 1, wherein the protrusion of the mold insulating pattern protrudes from the body of the mold insulating pattern by a preset distance that is greater than or equal to a thickness of the second gate dielectric layer.

5. The semiconductor device of claim 1, wherein the protrusion of the mold insulating pattern has a rectangular shape.

6. The semiconductor device of claim 1, wherein the protrusion of the mold insulating pattern is in a mirror-symmetric shape with respect to the body of the mold insulating pattern.

7. The semiconductor device of claim 1, wherein a side wall of the body of the mold insulating pattern, on which no protrusion is positioned, faces the upper conductive line with the second gate dielectric layer disposed therebetween.

8. The semiconductor device of claim 1, wherein the mold insulating pattern includes a low-k material having a smaller dielectric constant than each of a dielectric constant of the first gate dielectric layer and a dielectric constant of the second gate dielectric layer.

9. The semiconductor device of claim 1, wherein the vertical channel portion of the channel structure is spaced apart from the body of the mold insulating pattern.

10. The semiconductor device of claim 1, wherein the channel structure is a multi-layer structure including two or more layers.

11. The semiconductor device of claim 1, further comprising a lower conductive line positioned between the substrate and the channel structure,
wherein the lower conductive line is spaced apart from the upper conductive line with the channel structure, the first gate dielectric layer, and the second gate dielectric layer disposed therebetween, wherein an upper surface of the lower conductive line is in contact with a horizontal channel portion of the channel structure, and
the lower conductive line extends in the second horizontal direction.

12. The semiconductor device of claim 1, further comprising a conductive contact pattern connected to the channel structure.

13. The semiconductor device of claim 12, further comprising a capacitor structure connected to the conductive contact pattern.

14. A semiconductor device comprising:
a plurality of lower conductive lines positioned on a substrate and arranged in parallel to each other;
a mold insulating pattern positioned on the plurality of lower conductive lines, and extending in a first horizontal direction, wherein the mold insulating pattern defines a transistor region;
a plurality of channel structures arranged along the first horizontal direction in the transistor region, wherein each of the plurality of channel structures includes a vertical channel portion that faces a side wall of the mold insulating pattern;
a first gate dielectric layer overlapping a side wall of the plurality of channel structures;
a plurality of upper conductive line positioned on the plurality of channel structures in the transistor region, and including a side wall that faces the vertical channel portion of each of the plurality of channel structures, wherein the plurality of upper conductive lines extend in the first horizontal direction;
a second gate dielectric layer positioned between the plurality of channel structures and the plurality of upper conductive lines; and
a plurality of conductive contact patterns, each of which is connected to the vertical channel portion of each of the plurality of channel structures,
wherein a width in a second horizontal direction of a first portion, of the mold insulating pattern, that faces the vertical channel portion is greater than a width in the second horizontal direction of a second portion, of the mold insulating pattern, that does not face the vertical channel portion,
wherein the second horizontal direction intersects with the first horizontal direction.

15. The semiconductor device of claim 14, wherein the plurality of channel structures include an oxide semiconductor layer.

16. The semiconductor device of claim 14, wherein a difference between the width in the second horizontal direction of the first portion, of the mold insulating pattern, that faces the vertical channel portion and the width in the second horizontal direction of the second portion, of the mold insulating pattern, that does not face the vertical channel portion is twice or more a thickness of the second gate dielectric layer.

17. The semiconductor device of claim 14, wherein
a plurality of transistors including the plurality of channel structures are positioned in the transistor region,
the plurality of transistors include two transistors facing each other, and
the two transistors share a channel structure of the plurality of channel structures.

18. A semiconductor device comprising:
a printed circuit region positioned on a substrate and including a plurality of printed circuits;
a lower conductive line positioned on the printed circuit region and connected to the plurality of printed circuits;
a mold insulating pattern positioned on the lower conductive line and including a side wall that defines a transistor region;
a channel structure positioned in the transistor region, and including a lower surface and a vertical portion, wherein the lower surface of the channel structure is in contact with an upper surface of the lower conductive line, and the vertical channel portion of the channel structure faces the side wall of the mold insulating pattern;
a first gate dielectric layer and a second gate dielectric layer covering the channel structure in the transistor region;
an upper conductive line positioned on the first gate dielectric layer and the second gate dielectric layer in the transistor region, and including a side wall that faces the vertical channel portion of the channel structure; and
a conductive contact pattern connected to the vertical channel portion of the channel structure,
wherein the channel structure includes an oxide semiconductor layer, and
the mold insulating pattern includes a protrusion that protrudes in a direction that intersects with a direction in which the mold insulating pattern extends, wherein the protrusion of the mold insulating pattern has a preset thickness and is in contact with the vertical channel portion.

19. The semiconductor device of claim 18, wherein the preset thickness is greater than or equal to a thickness of the second gate dielectric layer.

20. The semiconductor device of claim 18, wherein the protrusion is mirror-symmetrical with respect to a body of the mold insulating pattern and has a rectangular shape.
